(19) United States
(12) Patent Application Publication
(10) Pub. No.: US 2012/0006391 A1
(43) Pub. Date: Jan. 12, 2012

(54) PHOTOVOLTAIC MODULE AND METHOD OF MANUFACTURING A PHOTOVOLTAIC MODULE HAVING AN ELECTRODE DIFFUSION LAYER

(75) Inventors: Kevin Michael Coakley, Mountain View, CA (US); Kunal Girotra, Mountain View, CA (US)

(73) Assignee: THINSILICON CORPORATION, Mountian View, CA (US)

(21) Appl. No.: 13/161,122

(22) Filed: Jun. 15, 2011

Related U.S. Application Data
(60) Provisional application No. 61/361,583, filed on Jul. 6, 2010.

(51) Int. Cl. H01L 31/0224; H01L 31/18; H01L 31/075

(52) U.S. Cl. 136/255; 136/256; 438/72; 257/E31.127

(57) ABSTRACT

A photovoltaic module that converts incident light received through a light transmissive cover sheet into a voltage is provided. The photovoltaic module includes a substrate, conductive upper and lower layers between the substrate and the cover sheet, and a semiconductor layer stack between the conductive upper and lower layers. The conductive lower layer includes an electrode diffusion layer between a lower electrode and a conductive light transmissive layer. The electrode diffusion layer restricts diffusion of the lower electrode of the conductive lower layer into the conductive light transmissive layer during deposition of the semiconductor layer stack. The incident light is converted by the semiconductor layer stack into the voltage potential between the conductive upper and lower layers.

### CROSS-REFERENCE TO RELATED APPLICATIONS

This application claims priority benefit to U.S. Provisional Application No. 61/361,583, which is entitled “Photovoltaic Module And Method Of Manufacturing A Photovoltaic Module Having An Electrode Diffusion Layer” and was filed on Jul. 6, 2010 (the “'583 Application”). The entire subject matter of the '583 Application is incorporated by reference.

### BACKGROUND OF THE INVENTION

The subject matter described herein relates to photovoltaic devices, such as photovoltaic modules. Some known photovoltaic devices include thin film solar modules made using thin films or layers of active silicon or another semiconductor material. Light is incident on the devices and enters into the silicon layers. If the light is absorbed by the silicon layers, the light may generate electrons and holes in the silicon. The electrons and holes are used to create electric current that may be drawn from the devices and applied to an external electric load.

Typically, conductive electrodes are located on opposite sides of the silicon layers. The electrodes are electrically coupled with the silicon layers and receive the electrons and holes to generate a voltage between the electrodes. For example, the electrons created by the incident light may flow to a top electrode located above the silicon layers while the holes created by the incident light flow to a bottom electrode located below the silicon layers. The photovoltaic module may include several electrically interconnected cells with each cell including one or more silicon layers between opposing top and bottom electrodes. The top electrode in one cell can be electrically coupled with the bottom electrode in an adjacent cell. The coupling of the top and bottom electrodes of adjacent cells permits the electrons or holes to flow between the cells. This flow of electrons or holes between the cells creates an electric current that may power an external circuit or load.

The electrodes in some known photovoltaic devices are formed from a metal or metal alloy. The metals or metal alloys of the electrodes tend to have relatively large diffusion coefficients (D). As a result, one or more of the electrodes may diffuse a significant distance into adjacent or neighboring layers or components of the photovoltaic devices when the electrodes are heated. For example, the bottom electrode may be deposited before the silicon layers are deposited. The silicon layers may be deposited onto or above the bottom electrode at elevated temperatures. The relatively high temperatures at which the silicon layers are deposited may cause the bottom electrode to diffuse into the silicon layers. Diffusion of the bottom electrode into the silicon layers may negatively impact the electrical coupling between the bottom electrode and the silicon layers. For example, such diffusion may cause the interface between the bottom electrode and the silicon layers to be a non-Ohmic contact.

A need exists for photovoltaic modules and methods of manufacturing photovoltaic modules where diffusion of one or more of the electrodes is reduced to prevent the electrodes from diffusing into or across the interface between the electrodes and the silicon or semiconductor layers of the modules.

### BRIEF DESCRIPTION OF THE INVENTION

In one embodiment, a photovoltaic module that converts incident light received through a light transmissive cover sheet into a voltage is provided. The photovoltaic module includes a substrate, conductive upper and lower layers between the substrate and the cover sheet, and a semiconductor layer stack between the conductive upper and lower layers. The conductive lower layer includes an electrode diffusion layer between an electrode and a conductive light transmissive layer. The electrode diffusion layer restricts diffusion of the electrode of the conductive lower layer into the conductive light transmissive layer during deposition of the semiconductor layer stack. The incident light is converted by the semiconductor layer stack into the voltage potential between the conductive upper and lower layers.

In another embodiment, a method for manufacturing a photovoltaic module having a substrate, a conductive electrode above the substrate, and a cover sheet through which incident light is received. The method includes depositing an electrode diffusion layer above the electrode, depositing a conductive light transmissive layer above the electrode diffusion layer, and depositing a semiconductor layer stack above the conductive light transmissive layer. The conductive light transmissive layer is electrically coupled with the electrode by the electrode diffusion layer. The electrode diffusion layer restricts diffusion of the electrode into the conductive light transmissive layer during deposition of the semiconductor layer stack. The method also includes depositing a conductive upper layer above the semiconductor layer stack. The semiconductor layer stack converts the incident light into a voltage between the electrode and the conductive upper layer.

In another embodiment, another photovoltaic module having a cover sheet through which incident light is received is provided. The photovoltaic module includes a substrate, an N-I-P stack of semiconductor layers disposed between the substrate and the cover sheet, a conductive upper layer between the N-I-P stack and the cover sheet, and a conductive lower layer disposed between the substrate and the N-I-P stack. The conductive upper and lower layers are electrically coupled with the N-I-P stack. The conductive lower layer includes an electrode and a conductive light transmissive layer with an electrode diffusion layer between the electrode and the conductive light transmissive layer. The electrode diffusion layer prevents diffusion of the electrode into the conductive light transmissive layer. The N-I-P stack converts the incident light into a voltage between the conductive upper and lower layers.

### BRIEF DESCRIPTION OF THE DRAWINGS

FIG. 1 is a perspective view of a schematic diagram of a photovoltaic (PV) module and a detail view of a cross-sectional portion of the PV module according to one embodiment.

FIG. 2 is a cross-sectional view of a PV cell along line 2-2 in FIG. 1 in accordance with one embodiment.

FIGS. 3A, 3B, and 3C illustrate a flowchart of a method for manufacturing a photovoltaic module in accordance with one embodiment.

FIG. 4 illustrates the PV module shown in FIG. 1 at a first stage of manufacture in accordance with one embodiment.

FIG. 5 illustrates the PV module shown in FIG. 1 at a second stage of manufacture in accordance with one embodiment.

FIG. 6 illustrates the PV module shown in FIG. 1 at a third stage of manufacture in accordance with one embodiment.

FIG. 7 illustrates the PV module shown in FIG. 1 at a fourth stage of manufacture in accordance with one embodiment.

FIG. 8 illustrates the PV module shown in FIG. 1 at a fifth stage of manufacture in accordance with one embodiment.

FIG. 9 illustrates the PV module shown in FIG. 1 at a sixth stage of manufacture in accordance with one embodiment.

FIG. 10 illustrates the PV module shown in FIG. 1 at a seventh stage of manufacture in accordance with one embodiment.

FIG. 11 illustrates the PV module shown in FIG. 1 at an eighth stage of manufacture in accordance with one embodiment.

FIG. 12 illustrates the PV module shown in FIG. 1 at a ninth stage of manufacture in accordance with one embodiment.

FIG. 13 illustrates the PV module shown in FIG. 1 at a tenth stage of manufacture in accordance with one embodiment.

### DETAILED DESCRIPTION OF THE INVENTION

The foregoing summary, as well as the following detailed description of certain embodiments of the subject matter set forth herein, will be better understood when read in conjunction with the appended drawings. As used herein, an element or step recited in the singular and proceeded with the word “a” or “an” should be understood as not excluding plural of said elements or steps, unless such exclusion is explicitly stated. Furthermore, references to “one embodiment” are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

In accordance with one or more embodiments described herein, a photovoltaic module having an electrode diffusion layer is provided. The electrode diffusion layer is deposited between a conductive electrode and a semiconductor layer stack of the photovoltaic module to prevent or reduce diffusion of the electrode into the semiconductor layer stack. In one embodiment, the electrode diffusion layer is provided between the electrode and a conductive light transmissive layer disposed between the semiconductor layer stack and the electrode. The electrode diffusion layer electrically couples the semiconductor layer stack with the electrode, or electrically couples the conductive light transmissive layer with the electrode, while also preventing or reducing diffusion of the electrode into the conductive light transmissive layer and/or the semiconductor layer stack.

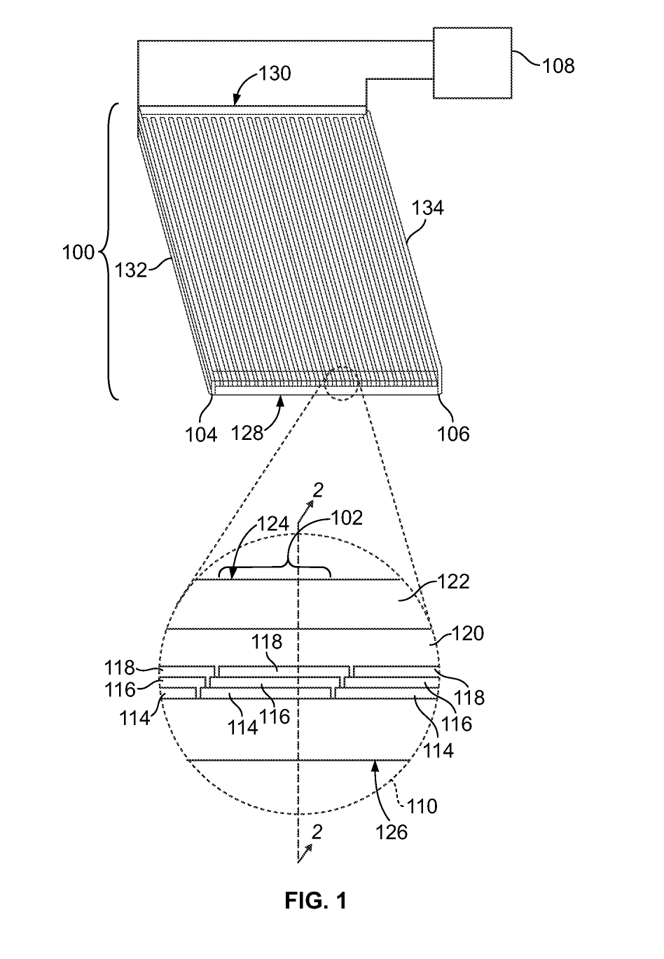

FIG. 1 is a perspective view of a schematic diagram of a photovoltaic (PV) module 100 and a detail view 110 of a cross-sectional portion of the PV module 100 according to one embodiment. The PV module 100 includes a plurality of PV cells 102 electrically connected with each other. For example, the PV module 100 may have one hundred or more PV cells 102 connected with one another in series. The outermost PV cells 102 that are located at or near opposite sides 132, 134 of the PV module 100 are electrically coupled with conductive leads 104, 106. The leads 104, 106 extend between opposite ends 128, 130 of the PV module 100. The leads 104, 106 are connected with a circuit 108 that includes an electrical load to which the current generated by the PV module 100 is collected or applied. For example, the current generated by the PV module 100 may be collected at an energy storage device, such as a battery and/or a device that consumes at least some of the current to perform a function.

The PV cells 102 include stacks of multiple layers. In one embodiment, the PV cells 102 include a supporting substrate 112, a conductive lower layer 114, a semiconductor layer stack 116, a light transmissive conductive upper layer 118, an adhesive layer 120 and a cover sheet 122. The light transmissive conductive upper layer 118 of one PV cell 102 is electrically connected with the conductive lower layer 114 in a neighboring PV cell 102 in order to electrically couple the PV cells 102 in series. The PV module 100 generates electric current from light that is incident on an upper surface 124 of the cover sheet 122, otherwise referred to as the film side of the PV module 100. The light passes through the cover sheet 122, the adhesive layer 120, and the light transmissive conductive upper layer 118. At least some of the light is absorbed by the semiconductor layer stack 116.

The semiconductor layer stack 116 may include multiple layers or films of doped and/or undoped semiconductor material. For example, the semiconductor layer stack 116 can include an N-I-P stack of an n-doped silicon layer, an intrinsic silicon layer on top of the n-doped layer, and a p-doped silicon layer on top of the intrinsic layer. The semiconductor layer stack 116 may include a P-I-N stack of a p-doped silicon layer, an intrinsic silicon layer on top of the p-doped layer, and an n-doped silicon layer on top of the intrinsic layer. In one embodiment, the semiconductor layer stack 116 is a tandem layer stack that includes several N-I-P and/or P-I-N stacks of semiconductor layers.

As the light passes through the semiconductor layer stack 116, at least some of the light is absorbed by the semiconductor layer stack 116. Some of the light may pass through the semiconductor layer stack 116 and be reflected off of the conductive lower layer 114 back into the semiconductor layer stack 116. Photons in the light excite electrons in the semiconductor layer stack 116. Depending on the wavelength of the light and the energy band gap of the materials in the semiconductor layer stack 116, the photons of the light may excite the electrons and cause the electrons to separate from atoms in the semiconductor layer stack 116. Complementary positive charges, or holes, are created when the electrons separate from the atoms. The electrons drift or diffuse through the semiconductor layer stack 116 and are collected at the conductive upper or lower layers 118, 114. The holes drift or diffuse through the semiconductor layer stacks 116 and are collected at the other of the conductive upper and lower layers 118, 114. For example, the electrons may be collected at the lower layer 114 while the holes are collected at the light transmissive conductive upper layer 118. The collection of the electrons and holes at the upper and lower layers 118, 114 generates voltage differences or voltage potentials in the PV cells 102.

The voltage differences in the PV cells 102 may be additive across the entire PV module 100. For example, the voltage difference in each of the PV cells 102 may be added together. As the number of PV cells 102 increases, the additive voltage difference across the series of PV cells 102 also may increase. Electric current is generated by the absorption of light and the flow of electrons and holes through the semiconductor layer stack 116. The voltage generated by each PV cell 102 is added in series across the plurality of PV cells 102. The current is then drawn to the circuit 108 through the connection of the leads 104, 106 to the upper and lower layers 118, 114 in the outermost PV cells 102. For example, a first lead 104 may be electrically connected to the light transmissive conductive upper layer 118 in the left-most PV cell 102 while a second lead 106 is electrically connected to the lower layer 114 in the right-most PV cell 102.

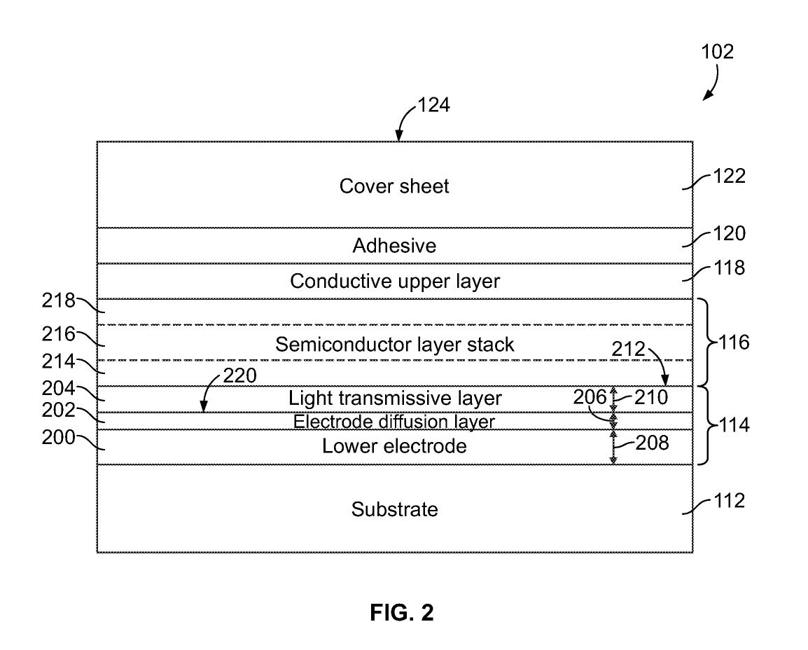

FIG. 2 is a cross-sectional view of the PV cell 102 along line 2-2 in FIG. 1 in accordance with one embodiment. The illustrated PV cell 102 is a substrate-configuration solar cell in that the PV cell 102 receives light through the upper surface 124 of the cover sheet 122 that is opposite of the substrate 112. The substrate 112 is a deposition surface on which the other films or layers of the PV cell 102 are deposited. The substrate 112 may include or be formed from an insulating or conductive material. In one embodiment, the substrate 112 is formed from a glass such as float glass or borosilicate glass. The substrate 112 may be opaque or light transmissive. For example, the substrate 112 may or may not permit light to pass through the substrate 112.

The conductive lower layer 114 is provided above the substrate 112. By “above,” it is meant that the conductive lower layer 114 is provided between the substrate 112 and the cover sheet 122 in the view shown in FIG. 2. The conductive lower layer 114 may include several layers or films that are electrically coupled with each other. The conductive lower layer 114 is electrically coupled with the semiconductor layer stack 116 such that electrons or holes that are generated by light that is absorbed or trapped in the semiconductor layer stack 116 are received into the conductive lower layer 114.

In the illustrated embodiment, the conductive lower layer 114 includes a lower electrode 200, an electrode diffusion layer 202, and a conductive light transmissive layer 204. The lower electrode 200 includes or is formed from a conductive material that may be reflective to incident light. For example, the lower electrode 200 may be formed from a metal such as silver (Ag), molybdenum (Mo), titanium (Ti), nickel (Ni), tantalum (Ta), aluminum (Al) or tungsten (W). In another embodiment, the lower electrode 200 is formed from an alloy that includes one or more of silver (Ag), molybdenum (Mo), titanium (Ti), nickel (Ni), tantalum (Ta), aluminum (Al) and tungsten (W). One example of such an alloy is a silver-tungsten alloy.

The lower electrode 200 may be deposited in a variety of thicknesses. For example, the lower electrode 200 may be deposited in a thickness that is sufficient to permit the conduction of current without significant resistance. By way of example only, the lower electrode 200 may be approximately 50 to 500 nanometers thick. In another embodiment, the lower electrode 200 may be approximately 200 nanometers thick. The thickness of the lower electrode 200 may be varied from these embodiments. For example, a variance of +/−10% or less of the thickness of the lower electrode 200 in these embodiments may be acceptable.

The electrode diffusion layer 202 is deposited above the lower electrode 200. For example, the electrode diffusion layer 202 may be deposited on the lower electrode 200 between the lower electrode 200 and the semiconductor layer stack 116. The electrode diffusion layer 202 prevents or restricts diffusion of the lower electrode 200 into the conductive light transmissive layer 204 and/or the semiconductor layer stack 116. During the deposition of one or more layers above the electrode diffusion layer 202, the lower electrode 200 may be heated. For example, the deposition of the semiconductor layer stack 116 may occur at elevated temperatures. The increase in temperature and thermal energy of the lower electrode 200 during deposition of the semiconductor layer stack 116 may cause the lower electrode 200 to diffuse into adjacent or abutting layers. For example, without the electrode diffusion layer 202 being present between the lower electrode 200 and the conductive light transmissive layer 204, the lower electrode 200 may diffuse into the conductive light transmissive layer 204 during deposition of the semiconductor layer stack 116. Diffusion of a reflective lower electrode 200 into the conductive light transmissive layer 204 may cause the conductive light transmissive layer 204 to become more opaque or less transmissive to light. As a result, the amount of light that can pass through the conductive light transmissive layer 204 may be reduced.

As described below, the conductive light transmissive layer 204 permits light that is not absorbed by the semiconductor layer stack 116 to pass through the conductive light transmissive layer 204 and be reflected by the electrode diffusion layer 202 and/or the lower electrode 200 back into the semiconductor layer stack 116. Increasing the opacity of the conductive light transmissive layer 204 may reduce the amount of light that is reflected back into the semiconductor layer stack 116. As a result, the efficiency of the photovoltaic module 100 (shown in FIG. 1) or cell 102 in converting incident light into voltage or current can be reduced.

The electrode diffusion layer 202 includes or is formed from a conductive material that electrically couples the conductive light transmissive layer 204 with the lower electrode 200. The electrode diffusion layer 202 conveys electrons collected at the conductive light transmissive layer 204 to the lower electrode 200. In one embodiment, the electrode diffusion layer 202 includes or is formed from a metal or metal alloy such as titanium or aluminum. Alternatively, the electrode diffusion layer 202 may include or be formed from one or more electrically insulative or semiconductive materials, such as a semiconductor material. For example, the electrode diffusion layer 202 may be formed from silicon nitride, silicon dioxide, alumina, or zinc oxide. The insulative or semiconductive materials may be doped in order to increase the conductivity of the electrode diffusion layer 202. For example, the electrode diffusion layer 202 may be formed from silicon dioxide that is doped with a p- or n-type dopant such as boron or phosphorus in order to make the electrode diffusion layer 202 more conductive. In another example, the electrode diffusion layer 202 includes alumina that is doped with aluminum. The alumina of the electrode diffusion layer 202 may include excess aluminum such that the electrode diffusion layer 202 is more conductive.

The electrode diffusion layer 202 may be reflective. For example, at least some of the incident light that passes through the semiconductor layer stack 116 without being absorbed may reflect off of the electrode diffusion layer 202 back toward the semiconductor layer stack 116. Alternatively, the electrode diffusion layer 202 may be a light transmissive layer. For example, at least some of the incident light that passes through the semiconductor layer stack 116 without being absorbed may also pass through the electrode diffusion layer 202 before being reflected by the lower electrode 200 back toward the semiconductor layer stack 116.

The electrode diffusion layer 202 may be deposited in a thickness 206 that is smaller or thinner than the adjacent lower electrode 200 and/or the conductive light transmissive layer 204. The thickness 206 of the electrode diffusion layer 202 is the distance that the electrode diffusion layer 202 extends from the lower electrode 200 to the conductive light transmissive layer 204. A thickness 208 of the lower electrode 200 may be the thickness of the lower electrode 200 that is deposited above the substrate 112. A thickness 210 of the conductive light transmissive layer 204 may be the distance that the conductive light transmissive layer 204 extends from the electrode diffusion layer 202 to the semiconductor layer stack 116. In one embodiment, the thickness 206 of the electrode diffusion layer 202 is smaller than the thickness 208 of the lower electrode 200 and/or the thickness 210 of the conductive light transmissive layer 204. The electrode diffusion layer 202 may be deposited in a relatively small thickness 206 as a thin film cap on the lower electrode 200 that limits diffusion of the lower electrode 200.

In one embodiment, the electrode diffusion layer 202 includes or is formed from silicon dioxide that is doped to increase the conductivity of the silicon dioxide. The thickness 206 of the silicon dioxide electrode diffusion layer 202 can be established to tune plasmon absorption wavelengths of incident light in the lower electrode 200. Plasmon absorption is the absorption of certain wavelengths of light in a metal layer, such as the lower electrode 200 in one or more embodiments. The thickness 206 of the electrode diffusion layer 202 may be established to cause a predetermined wavelength or set of wavelengths of incident light to be absorbed in the lower electrode 200. The wavelengths that are absorbed by the lower electrode 200 may differ from the wavelengths of the light that are absorbed or trapped by the semiconductor layer stack 116. For example, if light having wavelengths between 500 and 800 nanometers is to be absorbed in the semiconductor layer stack 116, then the thickness 206 of the electrode diffusion layer 202 may be established to cause wavelengths of the light outside of the range 500 to 800 nanometers to be absorbed by the lower electrode 200. In one embodiment, the thickness 206 and/or refractive index of the electrode diffusion layer 202 is based on the wavelengths of light that are absorbed in the semiconductor layer stack 116, or on the wavelengths of light that are absorbed in the lower electrode 200.

The conductive light transmissive layer 204 is located between the electrode diffusion layer 202 and the semiconductor layer stack 116. The conductive light transmissive layer 204 includes or is formed from a light transmissive material such as an optically clear or light-scattering layer of material. For example, the conductive light transmissive layer 204 may be formed from a transparent material. In another example, the conductive light transmissive layer 204 may be formed from a translucent material. One example of a material for the conductive light transmissive layer 204 is a transparent conductive oxide (TCO) material. For example, the conductive light transmissive layer 204 may include zinc oxide (ZnO), aluminum-doped zinc oxide (Al:ZnO), tin oxide (SnO₂), Indium Tin Oxide (ITO), fluorine doped tin oxide (SnO₂:F), and/or titanium dioxide (TiO₂).

The conductive light transmissive layer 204 electrically couples the semiconductor layer stack 116 with the electrode diffusion layer 202. The electrode diffusion layer 202 electrically couples the conductive light transmissive layer 204 with the lower electrode 200. In one embodiment, the conductive light transmissive layer 204 forms an Ohmic contact with the semiconductor layer stack 116. For example, an interface 212 between the conductive light transmissive layer 204 and the semiconductor layer stack 116 may provide an Ohmic contact such that a current-voltage (I-V) curve of current that is conducted between the semiconductor layer stack 116 and the conductive light transmissive layer 204 is approximately linear and/or symmetric. By Ohmic contact, it is meant that the interface 212 may be a non-Schottky diode or a non-rectifying junction between the semiconductor layer stack 116 and the conductive light transmissive layer 204. The electrode diffusion layer 202 may prevent the lower electrode 200 from diffusing into the semiconductor layer stack 116 and damaging the interface 212. For example, the electrode diffusion layer 202 may restrict the lower electrode 200 from diffusing into the semiconductor layer stack 202 and prevent formation of an Ohmic contact between the conductive lower layer 114 and the semiconductor layer stack 116.

The conductive light transmissive layer 204 may assist in the reflection of certain wavelengths of light off of the electrode diffusion layer 202 and/or the lower electrode 200. For example, the conductive light transmissive layer 204 may be deposited in a thickness that permits certain wavelengths of light that pass through the semiconductor layer stack 116 to pass through the conductive light transmissive layer 204, reflect off of the electrode diffusion layer 202 and/or the lower electrode 200, pass back through the conductive light transmissive layer 204 again, and into the semiconductor layer stack 116. Other wavelengths of the light may not be reflected back into the semiconductor layer stack 116. In doing so, the conductive light transmissive layer 204 may increase the efficiency of the PV cell 102 by increasing the amount of light that strikes the semiconductor layer stack 116 and generates electrons and holes. By way of example only, the conductive light transmissive layer 204 may be approximately 10 to 200 nanometers thick. As described above, diffusion of the lower electrode 200 into the conductive light transmissive layer 204 may increase the opacity of the conductive light transmissive layer 204. An increase in the opacity of the conductive light transmissive layer 204 may reduce the reflection of certain wavelengths of light off of the lower electrode 200 and/or the electrode diffusion layer 202.

For example, the thickness of the conductive light transmissive layer 204 may be approximately ¼ of the wavelength of light sought to be reflected off of the electrode diffusion layer 202 and/or the lower electrode 200, divided by the index of refraction of the material used in the conductive light transmissive layer 204. If the wavelength of light sought to be reflected from the electrode diffusion layer 202 and/or the lower electrode 200 and back into the semiconductor layer stack 116 is approximately 700 nanometers and the index of refraction of the conductive light transmissive layer 204 is approximately 2, then the thickness of the conductive light transmissive layer 204 may be approximately 87.5 nanometers. The thickness of the conductive light transmissive layer 204 may be varied from these embodiments. For example, a variance of +/−10% or less of the thickness of the conductive light transmissive layer 204 in these embodiments may be acceptable.

The semiconductor layer stack 116 is disposed above the conductive lower layer 114. For example, the semiconductor layer stack 116 may be located between the lower layer 114 and the cover sheet 122. The semiconductor layer stack 116 may be deposited directly onto the conductive light transmissive layer 204 or there may be one or more films or layers located between the conductive light transmissive layer 204 and the semiconductor layer stack 116.

In the illustrated embodiment, the semiconductor layer stack 116 is a multi-layer stack that includes an N-I-P stack of semiconductor layers. While only a single semiconductor layer stack 116 is shown, alternatively the PV module 100 (shown in FIG. 1) or cell 102 may include multiple semiconductor layer stacks 116. For example, the PV module 100 or cell 102 may include several N-I-P stacks 116 joined in series with each other. The illustrated semiconductor layer stack 116 includes an N-doped semiconductor layer 214, an intrinsic or lightly doped semiconductor layer 216, and a P-doped semiconductor layer 218. The N-doped semiconductor layer 214 may be a layer of silicon that is doped with an n-type dopant, such as phosphorus. The P-doped semiconductor layer 218 may be a layer of silicon that is doped with a p-type dopant, such as boron. The intrinsic semiconductor layer 216 may be a layer of silicon that is lightly doped with an n- or p-type dopant or that is not doped with either an n- or p-type dopant. The N-I-P stack of the semiconductor layers 214, 216, 218 is oriented such that the intrinsic semiconductor layer 216 is located between the N-doped semiconductor layer 214 and the P-doped semiconductor layer 218, with the N-doped semiconductor layer 214 disposed between the intrinsic semiconductor layer 216 and the conductive lower layer 114, and the P-doped semiconductor layer 218 disposed between the intrinsic semiconductor layer 216 and the light transmissive conductive upper layer 118. Alternatively, the order of the N- and P-doped semiconductor layers 214, 218 may be reversed. For example, the semiconductor layer stack 116 may be a P-I-N stack of semiconductor layers with the P-doped semiconductor layer 218 between the conductive lower layer 114 and the intrinsic semiconductor layer 216 and the N-doped semiconductor layer 214 between the intrinsic semiconductor layer 216 and the light transmissive conductive upper layer 118. The semiconductor layer stack 116 may be formed of silicon or a silicon alloy, such as silicon and germanium.

The N-doped, intrinsic, and P-doped semiconductor layers 214, 216, 218 may be amorphous layers. For example, the N-doped, intrinsic, and P-doped semiconductor layers 214, 216, 218 may not have a crystalline structure that extends throughout a majority of the N-doped, intrinsic, and P-doped semiconductor layers 214, 216, 218. Alternatively, one or more of the N-doped, intrinsic, and P-doped semiconductor layers 214, 216, 218 may be a microcrystalline, protocrystalline, or crystalline semiconductor layer.

The N-doped, intrinsic, and P-doped semiconductor layers 214, 216, 218 may be sequentially deposited at elevated temperatures. In one embodiment, the N-doped semiconductor layer 214 is deposited on the conductive light transmissive layer 204 at a temperature of at least 250 degrees Celsius, the intrinsic semiconductor layer 216 is deposited on the N-doped semiconductor layer 214 at a temperature of at least 250 degrees Celsius, and the P-doped semiconductor layer 218 is deposited on the intrinsic semiconductor layer 216 at a temperature of at least 150 degrees Celsius. By way of example only, the N-doped and intrinsic semiconductor layers 214, 216 may be deposited in Plasma Enhanced Chemical Vapor Deposition (PECVD) chambers at a temperature set point of the PECVD chamber of 250 degrees Celsius or more and 350 degrees Celsius or less. The P-doped semiconductor layer 218 may be deposited in a PECVD chamber at a temperature set point of the PECVD chamber of 150 degrees Celsius or more and 250 degrees Celsius or less.

The elevated temperatures at which the semiconductor layer stack 116 is deposited may heat up the components below the semiconductor layer stack 116, such as the lower electrode 200. One or more materials of which the lower electrode 200 is formed may have a relatively large diffusion coefficient (D). For example, the lower electrode 200 may include a material having a larger diffusion coefficient (D) than the materials of the electrode diffusion layer 202 and/or the conductive light transmissive layer 204. With a larger diffusion coefficient (D), the lower electrode 200 diffuses farther into adjacent layers than other materials having a lower diffusion coefficient (D). During the deposition of the semiconductor layer stack 116, the lower electrode 200 is heated and diffuses up into or toward the electrode diffusion layer 202. The electrode diffusion layer 202 restricts or prevents diffusion of the lower electrode 200 into the conductive light transmissive layer 204. For example, the electrode diffusion layer 202 may prevent the lower electrode 200 from diffusing into the conductive light transmissive layer 204.

The electrode diffusion layer 202 prevents the lower electrode 200 from diffusing past an interface 220 between the electrode diffusion layer 202 and the conductive light transmissive layer 204. For example, the lower electrode 200 may diffuse into, but not past the electrode diffusion layer 202. The electrode diffusion layer 202 may have a sufficiently small diffusion coefficient (D) that the electrode diffusion layer 202 does not significantly diffuse into the conductive light transmissive layer 204. For example, the electrode diffusion layer 202 may not diffuse into the conductive light transmissive layer 204 when the semiconductor layer stack 116 is deposited and the electrode diffusion layer 202 is heated. The diffusion coefficient (D) of the electrode diffusion layer 202 is smaller than the diffusion coefficient (D) of the lower electrode 200 in one embodiment.

The light transmissive conductive upper layer 118 is deposited above the P-doped semiconductor layer 218. The light transmissive conductive upper layer 118 includes a metal or metal alloy that is electrically coupled with the P-doped semiconductor layer 218 such that electrons or holes generated in the semiconductor layer stack 116 may reach the light transmissive conductive upper layer 118. The light transmissive conductive upper layer 118 is at least partially transparent to light in order to permit incident light to pass through the light transmissive conductive upper layer 118 and reach the semiconductor layer stack 116. The adhesive layer 120 is placed on the light transmissive conductive upper layer 118 to secure the cover sheet 122 to the light transmissive conductive upper layer 118.

In operation, incident light passes through the cover sheet 122 and the light transmissive conductive upper layer 118 to enter the semiconductor layer stack 116. At least some of the light is absorbed in the intrinsic semiconductor layer 216 to create electrons and holes. The electrons and holes flow to the conductive upper and lower layers 118, 114 to generate a voltage potential or electric potential in the cell 102 between the conductive upper and lower layers 118, 114. Although not shown in the illustrated embodiment, additional semiconductor layer stacks and/or other layers may be provided in the PV cell 102. For example, another N-I-P semiconductor layer stack may be deposited above the semiconductor layer stack 116, such as between the semiconductor layer stack 116 and the light transmissive conductive upper layer 118.

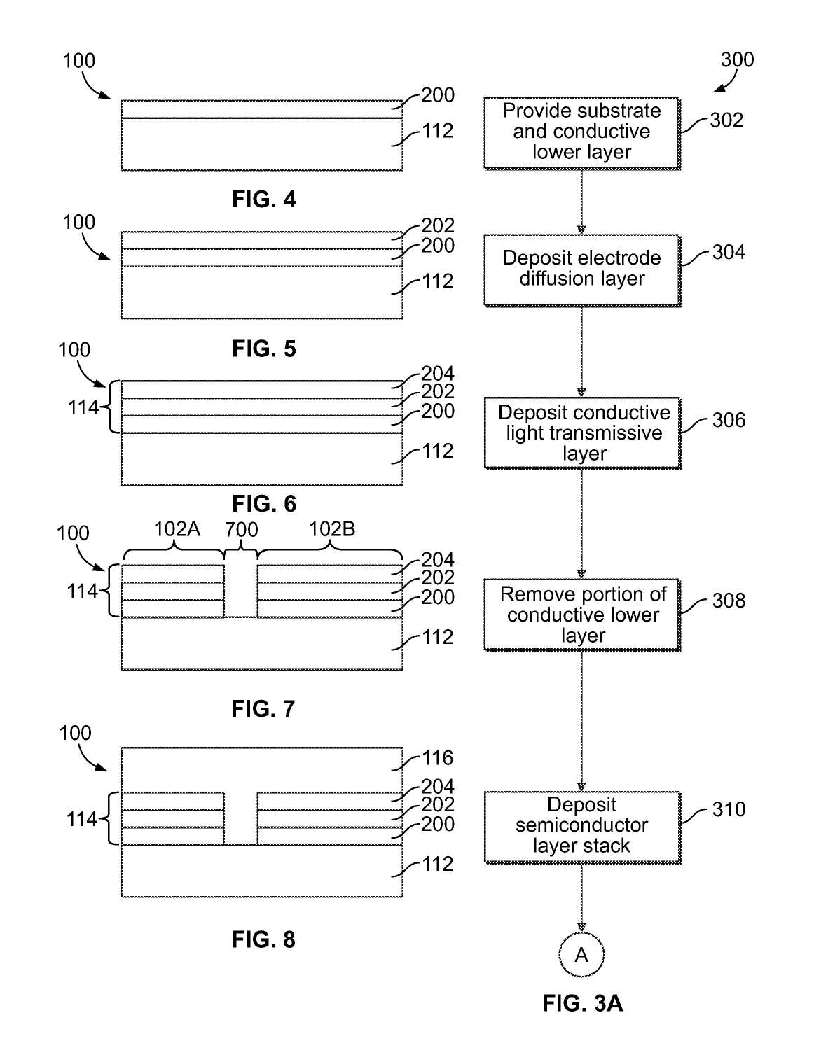

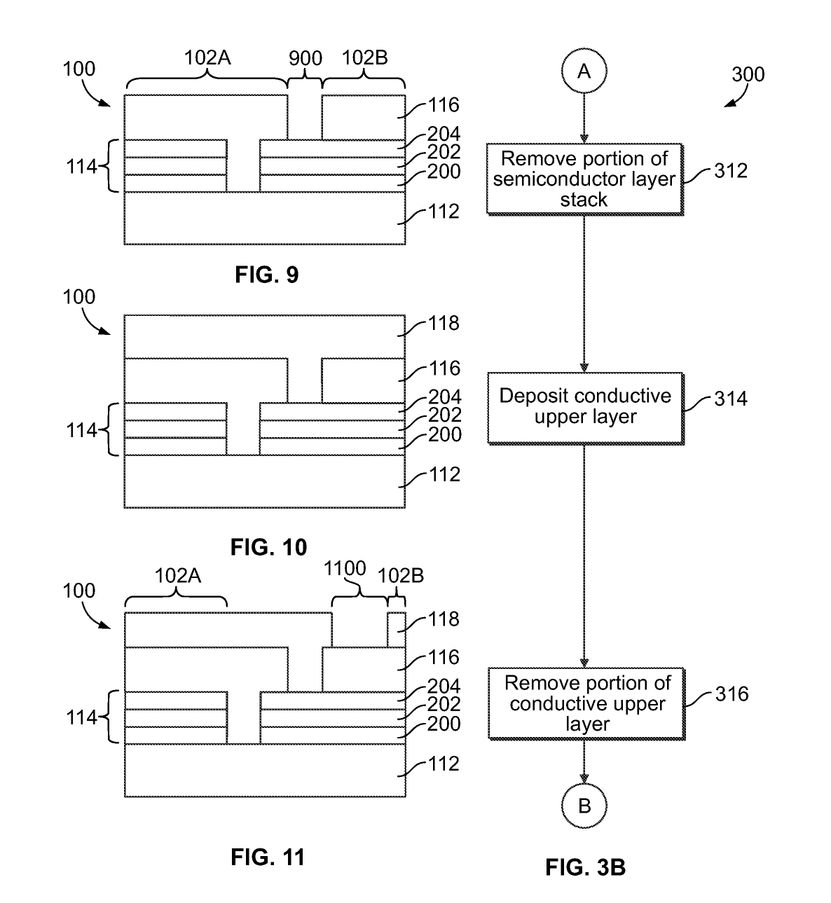

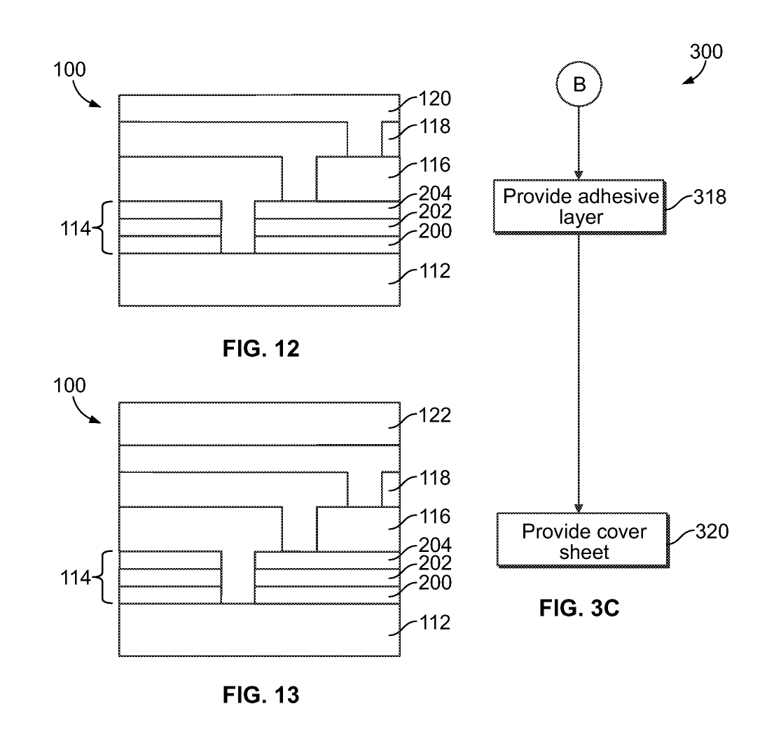

FIGS. 3A, 3B, and 3C illustrate a flowchart of a method 300 for manufacturing a photovoltaic module in accordance with one embodiment. FIGS. 4 through 13 illustrate the PV module 100 at various stages during the manufacture of the PV module 100 in accordance with one embodiment. The stages shown in FIGS. 4 through 12 correspond with several of the operations described in the method 300 of FIGS. 3A, 3B, and 3C.

At 302, a substrate and a lower electrode are provided. For example, as shown in FIG. 4, the substrate 112 and the lower electrode 200 may be provided. The lower electrode 200 may be previously deposited onto the substrate 112 with the substrate 112 and lower electrode 200 provided as a single unit or body.

At 304, an electrode diffusion layer is deposited above the lower electrode. As shown in FIG. 5, the electrode diffusion layer 202 may be deposited onto the lower electrode 200, such as by sputtering the electrode diffusion layer 202 directly onto the lower electrode 200.

At 306, a conductive light transmissive layer is deposited above the electrode diffusion layer to form a conductive lower layer. For example, the conductive light transmissive layer 204 may be sputtered or otherwise deposited onto the electrode diffusion layer 202 to form the conductive lower layer 114 with the electrode diffusion layer 202 and the conductive light transmissive layer 204, as shown in FIG. 6. The conductive light transmissive layer 204 is positioned such that the electrode diffusion layer 202 is disposed to prevent diffusion of the lower electrode 200 into the conductive light transmissive layer 204. In the illustrated embodiment, for example, the electrode diffusion layer 202 is located between the lower electrode 200 and the conductive light transmissive layer 204.

At 308, a portion of the conductive lower layer is removed. As shown in FIG. 7, a portion 700 of the conductive lower layer 114 is removed to electrically separate the conductive lower layers 114 in neighboring PV cells 102A, 102B from each other. The portion 700 may be removed using a chemical etch, a focused beam of energy, such as a laser beam, and the like.

At 310, a semiconductor layer stack is deposited above the conductive light transmissive layer. As shown in FIG. 8, the semiconductor layer stack 116 may be deposited onto the conductive light transmissive layer 204 such that the semiconductor layer stack 116 is electrically coupled with the conductive light transmissive layer 204. The semiconductor layer stack 116 may be deposited in a sequence of layers. For example, the semiconductor layer stack 116 may be deposited by depositing the N-doped semiconductor layer 214 (shown in FIG. 2) on the conductive light transmissive layer 204, followed by depositing the intrinsic semiconductor layer 216 (shown in FIG. 2) on the N-doped semiconductor layer 216, and followed by depositing the P-doped semiconductor layer 218 (shown in FIG. 2) on the intrinsic semiconductor layer 216. The deposition of one or more of the semiconductor layers 214, 216, 218 may occur at an elevated temperature. For example, the N-doped and intrinsic semiconductor layers 214, 216 may be deposited at temperatures between 250 to 350 degrees Celsius.

With reference to FIG. 3B, at 312, a portion of the semiconductor layer stack is removed between neighboring PV cells. As shown in FIG. 9, a portion 900 of the semiconductor layer stack 116 is removed to separate the semiconductor layer stacks 116 in neighboring PV cells 102A, 102B from each other. The portion 900 may be removed using a chemical etch, a focused beam of energy, such as a laser beam, and the like.

At 314, a conductive upper layer is deposited above the semiconductor layer stack. For example, the light transmissive conductive upper layer 118 may be deposited directly onto the semiconductor layer stack 116, as shown in FIG. 10.

At 316, a portion of the light transmissive conductive upper layer is removed. As shown in FIG. 11, a portion 1100 of the light transmissive conductive upper layer 118 is removed to electrically separate the light transmissive conductive upper layers 118 in neighboring PV cells 102A, 102B from each other. In the illustrated embodiment of FIG. 11, only a section of the PV cell 102B is shown. The portion 1100 may be removed using a chemical etch, a focused beam of energy, such as a laser beam, and the like.

With reference to FIG. 3C, at 318, an adhesive layer is provided on the conductive upper layer. For example, the adhesive layer 120 may be sputtered or otherwise deposited onto the light transmissive conductive upper layer 118, as shown in FIG. 12.

At 320, a cover sheet is coupled to the adhesive layer. As shown in FIG. 13, the light transmissive cover sheet 122 may be joined to the adhesive layer 120. Incident light passes through the cover sheet 122 and the light transmissive conductive upper layer 118. The light is absorbed by the semiconductor layer stack 116 and/or is reflected by the conductive lower layer 114 back into the semiconductor layer stack 116. The absorbed light generates electrons and holes that flow to the light transmissive conductive upper layer 118 or the conductive lower layer 114. As shown in FIG. 13, the light transmissive conductive upper layer 118 of the cell 102A is electrically coupled with the lower layer 114 of the cell 102B. The electrical current that flows from the semiconductor layer stack 116 to the light transmissive conductive upper layer 118 of the cell 102A is conducted to the lower layer 114 of the cell 102B. This flow of current continues throughout the PV module 100.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the subject matter set forth herein without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the subject matter described herein should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure.

What is claimed is:

1. A photovoltaic module configured to convert incident light received through a light transmissive cover sheet into a voltage, the photovoltaic module including:
a substrate;
conductive upper and lower layers disposed between the substrate and the cover sheet, the conductive lower layer including an electrode diffusion layer between a lower electrode and a conductive light transmissive layer; and
a semiconductor layer stack deposited between the conductive lower and upper layers, the electrode diffusion layer restricting diffusion of the lower electrode of the conductive lower layer into the conductive light transmissive layer during deposition of the semiconductor layer stack, wherein the incident light is converted by the semiconductor layer stack into the voltage between the conductive upper and lower layers.

2. The photovoltaic module of claim 1, wherein the electrode diffusion layer electrically couples the lower electrode with the conductive light transmissive layer.

3. The photovoltaic module of claim I, wherein the electrode diffusion layer has a diffusion coefficient that is smaller than a diffusion coefficient of the lower electrode.

4. The photovoltaic module of claim 1, wherein the electrode diffusion layer is light transmissive such that at least some of the incident light passes through the electrode diffusion layer and is reflected off of the lower electrode.

5. The photovoltaic module of claim 1, wherein the electrode diffusion layer is formed from a metal or metal alloy.

6. The photovoltaic module of claim 1, wherein the electrode diffusion layer is formed from an electrically insulative or semiconductive material doped with a conductive material.

7. The photovoltaic module of claim 1, wherein a thickness of the electrode diffusion layer that extends from the lower electrode to the conductive light transmissive layer is based on one or more wavelengths of the incident light that is absorbed by the semiconductor layer stack.

8. A method for manufacturing a photovoltaic module having a substrate, a conductive lower electrode above the substrate, and a cover sheet through which incident light is received, the method including:
depositing an electrode diffusion layer above the lower electrode;
depositing a conductive light transmissive layer above the electrode diffusion layer, the conductive light transmissive layer electrically coupled with the lower electrode by the electrode diffusion layer;
depositing a semiconductor layer stack above the conductive light transmissive layer, the electrode diffusion layer restricting diffusion of the lower electrode into the conductive light transmissive layer during deposition of the semiconductor layer stack; and
depositing a conductive upper layer above the semiconductor layer stack, wherein the semiconductor layer stack converts the incident light into a voltage potential between the lower electrode and the conductive upper layer.

9. The method of claim 8, wherein the electrode diffusion layer electrically couples the lower electrode with the conductive light transmissive layer.

10. The method of claim 8, wherein the electrode diffusion layer has a diffusion coefficient that is smaller than a diffusion coefficient of the lower electrode.

11. The method of claim 8, wherein the electrode diffusion layer is light transmissive such that at least some of the incident light passes through the electrode diffusion layer and is reflected off of the lower electrode.

12. The method of claim 8, wherein the electrode diffusion layer is deposited as a metal or metal alloy.

13. The method of claim 8, wherein the electrode diffusion layer is deposited be depositing an electrically insulative or semiconductive material that is doped with a conductive material.

14. The method of claim 8, wherein a thickness of the electrode diffusion layer that extends from the lower electrode to the conductive light transmissive layer is based on one or more wavelengths of the incident light that is absorbed by the semiconductor layer stack.

15. The method of claim 8, further comprising removing a portion of the lower electrode, the electrode diffusion layer, and the conductive light transmissive layer after the conductive light transmissive layer is deposited, the removing operation separating the lower electrodes, the electrode diffusion layers, and the conductive light transmissive layers in adjacent photovoltaic cells of the module.

16. The method of claim 8, wherein the depositing of the semiconductor layer stack is performed at a temperature between 250 and 350 degrees Celsius.

17. A photovoltaic module having a cover sheet through which incident light is received, the photovoltaic module comprising:
a substrate
an N-I-P stack of semiconductor layers disposed between the substrate and the cover sheet;
a conductive upper layer electrically coupled with the N-I-P stack and disposed between the N-I-P stack and the cover sheet; and
a conductive lower layer electrically coupled with the N-I-P stack and disposed between the substrate and the N-I-P stack, the conductive lower layer including a lower electrode and a conductive light transmissive layer with an electrode diffusion layer between the lower electrode and the conductive light transmissive layer, the electrode diffusion layer preventing diffusion of the lower electrode into the conductive light transmissive layer, wherein the N-I-P stack converts the incident light into a voltage between the conductive upper and lower layers.

18. The photovoltaic module of claim 17, wherein the electrode diffusion layer electrically couples the conductive light transmissive layer with the lower electrode.

19. The photovoltaic module of claim 17, wherein the electrode diffusion layer includes an electrically insulative or semiconductive material doped with a conductive material.

20. The photovoltaic module of claim 17, wherein the electrode diffusion layer extends from the lower electrode to the conductive light transmissive layer and prevents the lower electrode from diffusing into the conductive light transmissive layer during deposition of the semiconductor layer stack.
